(19) United States
(12) Patent Application Publication
(10) Pub. No.: US 2004/0121604 A1
(43) Pub. Date: Jun. 24, 2004

(54) Method of etching a low-k dielectric layer

(76) Inventors: Chun-Feng Nieh, Hsinchu (TW); Ching-Fan Wang, Hsinchu (TW); Fung-Hsu Cheng, Taoyuan (TW); Zhen-Long Chen, Tainan (TW)

Correspondence Address: BIRCH STEWART KOLASCH & BIRCH, PO BOX 747, FALLS CHURCH, VA, 22040-0747, US

(21) Appl. No.: 10/321,565

(22) Filed: Dec. 18, 2002

(51) Int. Cl. H01L 21/311

(52) U.S. Cl. 438/694

(57) ABSTRACT

A method of etching a low-k dielectric layer. A substrate having a low-k dielectric layer to be etched, on which an amorphous carbon doped layer is formed over the low-k dielectric layer by plasma enhanced chemical vapor deposition (PECVD), a resist layer is formed over the amorphous carbon doped layer , and the resist layer is patterned to define a first opening thereby forming a resist mask. The amorphous carbon doped layer is etched to define a second opening, thereby forming a hardmask, the resist mask is stripped, and the low-k dielectric layer not covered by the hardmask is etched to form a third opening as a trench or via.

### BACKGROUND OF THE INVENTION

1. Field of the Invention

The present invention relates to a method of etching a low-k dielectric layer with an amorphous carbon doped layer as a hardmask, and more specifically to a method of etching a low-k dielectric layer to form a trench or via using an amorphous carbon doped layer as a hardmask.

2. Description of the Related Art

In the back end of semiconductor chip fabricating process, the metal systems necessary to connect the devices and different layers are added to the chip by a process called metallization, comprising forming a dielectric layer over a semiconductor substrate, planarizing and patterning the dielectric layer to form trenches and/or vias, and filling the trenches and/or vias to forming conducting wires and/or via plugs. A chemical mechanical polishing process is then performed to planarize the surface of the semiconductor substrate.

It is important to develop a smaller, more powerful semiconductor chip with denser electronic device and interconnect populations. However, parasitic capacitance between the metal interconnects, which leads to RC delay and crosstalk, increases correspondingly. Therefore, to reduce the parasitic capacitance, increasing the speed of conduction between the metal interconnections, a low-k dielectric material is commonly employed to form an interlayer dielectric (ILD) layer.

At the same time, the design rule below 100 nm (0.1 μm) further requires denser interconnects, meaning narrower and narrower openings for vias or trenches, and increase of aspect ratio of the openings in an ILD layer.

The most critical is the resolution capability in lithography. The laser light source of the deep ultraviolet (DUV) spectrum, whose wavelength is equal to or below 248 nm, is used in lithography. A dielectric anti-reflection coating combined with a thinner resist layer can effectively increase small-geometry control in lithography and provide the needed resolution. Etch selectivities of typical low-k dielectric materials formed by spin-on or CVD, such as SiLK and black diamond, with respect to the resist material used in DUV lithography are not sufficiently high to permit thinner resist layers to be used alone to etch trench or via openings.

Instead, a more durable material must be deposited over the low-k dielectric layer, providing both of good anti-reflection function for photo patterning and masking function for RIE etching. The hardmask material, having a substantially lower etch rate during RIE, may be deposited relatively thinly and can therefore be easily patterned with a thin resist mask.

U.S. Pat. No. 6,319,822 discloses a TiNₓC_{y} layer formed by MOCVD (metal organic chemical vapor deposition) as a hardmask to etch an opening for a contact or a via in a PMD (pre-metal dielectric) layer. However, MOCVD is not a typical deposition method for the low-k dielectric layer, causing cost and process complexity.

### SUMMARY OF THE INVENTION

Therefore, the main object of the present invention is to provide a method of etching a low-k dielectric layer that allows an opening as a trench or a via on BEOL process with 0.13 μm process or beyond.

Another object of the present invention is to provide a method of etching a low-k dielectric layer that comprises forming a hardmask using the same apparatus and process as those used in the deposition of low-k dielectric layer, simplifying the process and lowering the cost.

In order to achieve the above object, the present invention provides a method of etching a low-k dielectric layer, comprising forming an amorphous carbon doped layer as a etching hardmask. First, a substrate having a low-k dielectric layer to be etched is provided. Then, an amorphous carbon doped layer over the low-k dielectric layer is formed by plasma enhanced chemical vapor deposition (PECVD). Next, a resist layer is formed over the amorphous carbon doped layer, and patterned to define an opening, thereby forming a resist mask. Next, etch the amorphous carbon doped layer to define a hardmask. Further, the resist mask is stripped. Finally, the low-k dielectric layer is etched to form an opening.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 through FIG. 7 are cross-sections illustrating manufacturing steps of etching a low-k dielectric layer comprising forming an amorphous carbon doped layer as a hardmask to form an opening as a trench or a via to form an interconnect in the low-k dielectric layer in accordance with the preferred of the present invention.

### DETAILED DESCRIPTION OF THE INVENTION

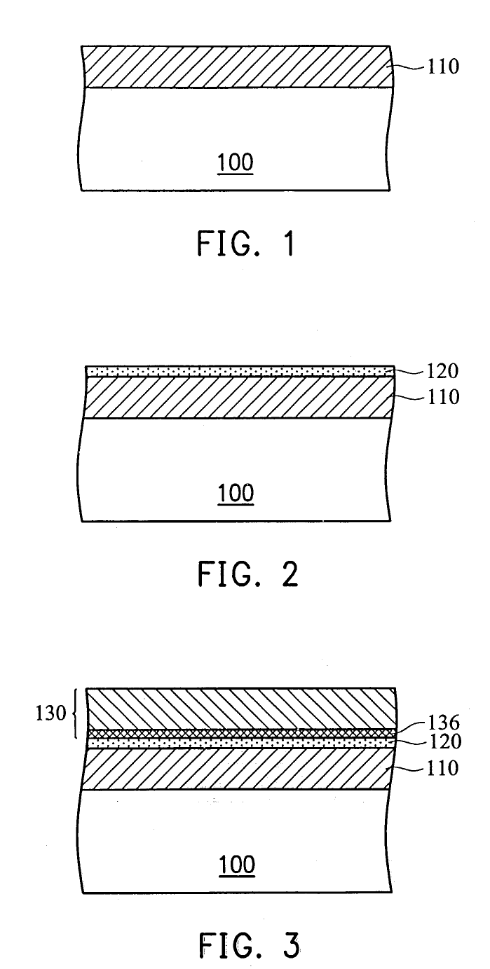

FIG. 1 through FIG. 7 are cross-sections illustrating manufacturing steps of etching a low-k dielectric layer for 0.13 μm generation or beyond. The method comprises forming an amorphous carbon doped layer as a hardmask to form an opening as a trench or a via in accordance with the present invention.

First, in FIG. 1, a substrate 100 comprising device regions (not shown) is provided. A low-k dielectric layer 110, such as black diamond and other organic or inorganic low k dielectric layer, is deposited over the substrate 100. Low k dielectric layer 110 is usually about 3000 Å to 6000 Å thick for a damascene process.

Next, in FIG. 2, an amorphous carbon doped layer 120 having a thickness between about 300 and 1000 Å over low-k dielectric layer 110 is formed by plasma enhanced chemical vapor deposition (PECVD), using the same deposition apparatus as that used in the deposition of low-k dielectric layer. C₃H₆ gas is used as one precursor ionized by a RF-field with a frequency between about 380 KHZ and about 13.56 MHZ and the ionized carbon particles collide with low-k dielectric layer 110 at a temperature between 300° C. and 450° C. to form amorphous carbon doped layer 120 over low-k dielectric layer 110. Note that amorphous carbon doped layer 120 may further serve as an anti-reflective layer in the following patterning step.

Next, in FIG. 3, resist layer 130 is formed by a method such as spin coating on amorphous carbon doped layer 120. An anti-reflection coating (ARC) layer 136 is provided at the bottom or top of resist layer 130 to combine with amorphous carbon doped layer 120 to limit reflection in the following patterning step. In the present invention, ARC layer 136 is at the bottom of resist layer 130.

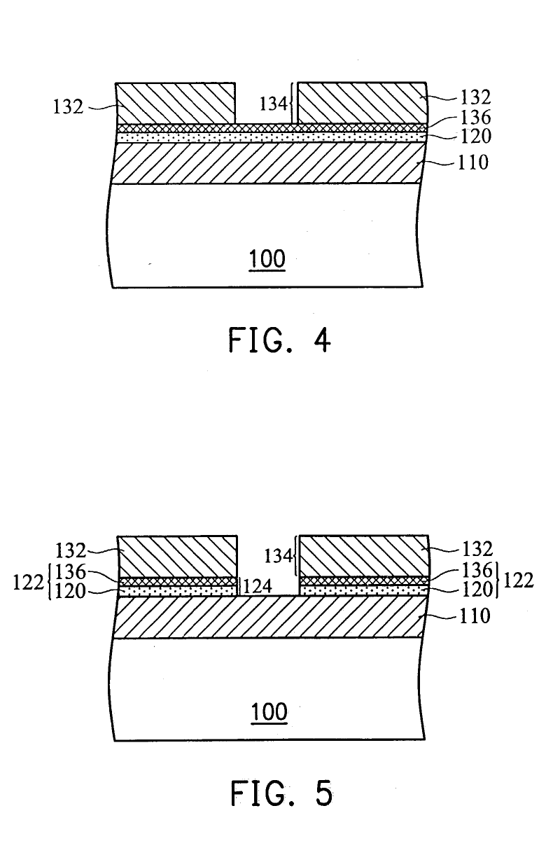

Next, in FIG. 4, resist layer 130 is patterned; resist opening 134 is formed and resist mask 132 is formed to serve as a mask for etching through ARC layer 136 and amorphous carbon doped layer 120.

Next, in FIG. 5, a part of ARC layer 136 and amorphous carbon doped layer 120 under resist opening 134 is etched by the plasma containing oxygen ions. Hardmask opening 124 is formed and the remained amorphous carbon doped layer 120 functions as hardmask 122 for etching low-k dielectric layer 110 under hardmask opening 124, not covered by hardmask 122.

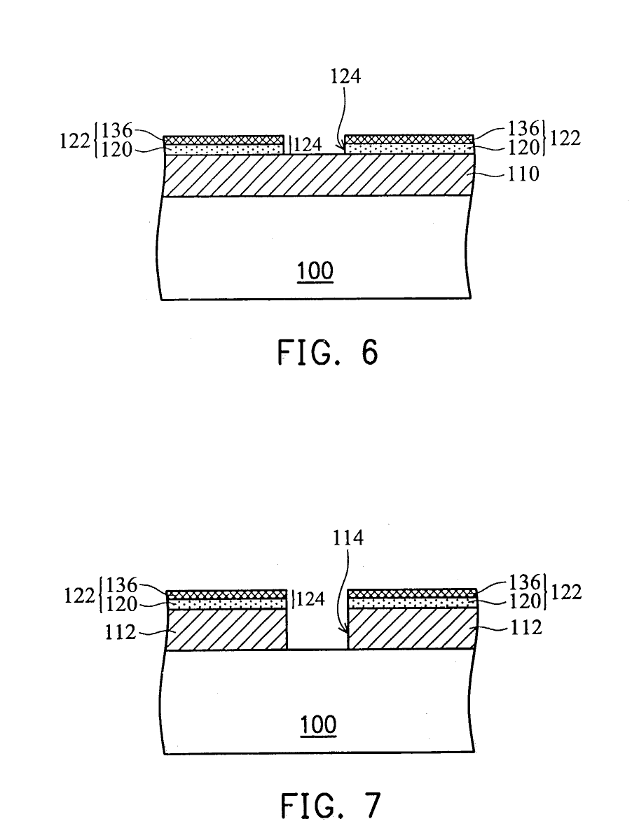

Next, in FIG. 6, resist mask 132 is stripped to expose hardmask 122.

Finally, in FIG. 7, a part of low-k dielectric layer 110, under hardmask opening 124, not covered by hardmask 112 is etched by RIE using O2, N2, or a fluorine-containing gas. Dielectric opening 114 is formed in low-k dielectric layer 110 as a trench or a via to form an interconnect (not shown).

Compared with the prior art, one of the advantages provided by the present invention is reduction of the width of the opening formed in the low-k dielectric layer, serving as a trench or a via to form an interconnect. The width of the opening formed in the low-k dielectric layer, serving as a trench or a via to form an interconnect, can be reduced to as low as 0.13 μm, thereby achieving the main object of the present invention.

Another advantage provided by the present invention is to provide a method of etching a low-k dielectric layer that comprises forming a hardmask using the apparatus and process of PECVD typical in the deposition of low-k dielectric layer for simplifying the process and lowering the cost, thereby achieving another object of the present invention.

Although the present invention has been particularly shown and described above with reference to two specific embodiments, it is anticipated that alterations and modifications thereof will no doubt become apparent to those skilled in the art. It is therefore intended that the following claims be interpreted as covering all such alteration and modifications as fall within the true spirit and scope of the present invention.

What is claimed is:

1. A method of etching a low-k dielectric layer, comprising:
providing a substrate having a low-k dielectric layer to be etched;
forming an amorphous carbon doped layer over the low-k dielectric layer;
forming a resist layer over the amorphous carbon doped layer;
patterning the resist layer to define a first opening, thereby forming a resist mask;
etching the amorphous carbon doped layer not covered by the resist mask to define a second opening in the amorphous carbon doped layer, thereby forming a hardmask;
stripping the resist mask; and
etching the low-k dielectric layer not covered by the hardmask to form a third opening.

2. The method as claimed in claim 1, wherein the thickness of the low-k dielectric layer is between about 3000 and 6000 Å.

3. The method as claimed in claim 1, wherein the thickness of the amorphous carbon doped layer is between about 300 and 1000 Å.

4. The method as claimed in claim 1, further comprising forming an anti-reflection coating (ARC) layer after the amorphous carbon doped layer is deposited.

5. The method as claimed in claim 1, wherein the low-k dielectric layer comprises a black diamond layer.

6. The method as claimed in claim 1, wherein the resist mask is patterned by a light with a wavelength of equal to or less than about 248 nm.

7. A method of etching a black diamond layer, comprising:
providing a substrate to be etched having a black diamond layer as a low-k dielectric layer;
in situ formation of an amorphous carbon doped layer over the black diamond layer by plasma enhanced chemical vapor deposition (PECVD);
forming a resist layer over the amorphous carbon doped layer;
patterning the resist layer to define a first opening thereby forming a resist mask;
etching the amorphous carbon doped layer not covered by the resist mask to define a second opening in the amorphous carbon doped layer, thereby forming a hardmask;
stripping the resist mask; and
etching the black diamond layer not covered by the hardmask to form a third opening.

8. The method as claimed in claim 7, wherein the thickness of the black diamond layer as a low-k dielectric layer is between about 3000 and 6000 Å.

9. The method as claimed in claim 7, wherein the thickness of the amorphous carbon doped layer is between about 300 and 1000 Å.

10. The method as claimed in claim 7, further comprising forming an anti-reflection coating (ARC) layer after the amorphous carbon doped layer is deposited.

11. The method as claimed in claim 7, wherein the resist mask is patterned by a light with a wavelength equal to or less than about 248 nm.
